(19) United States
(12) Patent Application Publication
(10) Pub. No.: US 2025/0096069 A1
(43) Pub. Date: Mar. 20, 2025

(54) POWER MODULE AND METHOD OF FABRICATING THE SAME

(71) Applicant: Infineon Technologies AG, Neubiberg (DE)

(72) Inventors: Adrian Lis, Regensburg (DE); Thomas Schmid, Regensburg (DE); Ewald Günther, Regenstauf (DE)

(21) Appl. No.: 18/816,500

(22) Filed: Aug. 27, 2024

(30) Foreign Application Priority Data
Sep. 18, 2023 (DE) 102023209025.2

(51) Int. Cl. H01L 23/373; H01L 23/31; H01L 23/367; H01L 23/50; H02M 1/32

(52) U.S. Cl. CPC H01L 23/3736; H01L 23/3157; H01L 23/3672; H01L 23/50; H02M 1/327

(57) ABSTRACT

A power module includes a substrate, one or more semiconductor dies mounted to the substrate, a first external power connection electrically connected to a first power terminal of at least one of the one or more semiconductor dies, and an encapsulant at least partially encapsulating the first external power connection. A portion of the first external power connection and at least parts of an outer surface of the substrate are exposed from the encapsulant. A heatsink is mounted to the first external power connection.

### TECHNICAL FIELD

The present disclosure relates to power modules and power module assemblies, in particular to the heat dissipation of power modules.

### BACKGROUND

Many different applications such as automotive and industrial applications utilize power modules that comprise multiple power devices in a single package or housing. Power modules may include power conversion circuits such as single and multi-phase half-wave rectifiers, single and multi-phase full-wave rectifiers, voltage regulators, inverters, etc. High performance power modules are designed for minimal power losses and can improve the energy efficiency of a power system. Power modules can form part of power efficient solutions to reduce or prevent anthropogenic emissions of greenhouse gases. For instance, hybrid electric vehicles (HEVs) or electric vehicles (EVs) utilize power modules to perform power conversion, inversion, switching, etc., in a power efficient manner.

The maximum output current of high-performance power modules is often limited by the external power terminals. The external power terminals are usually made of a conducting material such as copper and have a different thermal expansion coefficient than the material that is encapsulating the semiconductor chips and/or forms the housing of the power module. Thus, the protrusions of the external power terminals through the encapsulation material should be kept to a minimum in order to avoid stressing/cracking of the encapsulation material and thus risking electric isolation failures. On the other hand, the narrower the external contacts are at the protrusion section of the encapsulating housing, the hotter they get during operation when a lot of current is carried through these narrow sections.

The present disclosure provides a solution to address the above described issue.

### SUMMARY

A power module is disclosed comprising a substrate, one or more semiconductor dies mounted to the substrate, a first external power connection electrically connected to a first power terminal of at least one of the one or more semiconductor dies, an encapsulant at least partially encapsulating the first external power connection wherein a portion of the first external power connection and at least parts of an outer surface of the substrate are exposed from the encapsulant, a heatsink mounted to the first external power connection.

A system is disclosed that comprises a cooler, a power module as described above, wherein the substrate is mounted to a first surface of the cooler and wherein the heatsink is an extension of the cooler extending beyond the encapsulation of the power module.

A power module is disclosed comprising a substrate, one or more semiconductor dies mounted to the substrate; a first external power connection electrically connected to a first power terminal of at least one of the one or more semiconductor dies, an encapsulant at least partially encapsulating the first external power connection wherein an external end portion of the first external power connection and at least parts of an outer surface of the substrate are exposed from the encapsulant, wherein parts of the external end portion of the first external power connection are bent to form a coplanar surface with the outer surface of the substrate that are exposed from the encapsulant.

Those skilled in the art will recognize additional features and advantages upon reading the following detailed description, and upon viewing the accompanying drawings.

### BRIEF DESCRIPTION OF THE DRAWINGS

The present disclosure is illustrated by way of example, and not by way of limitation, in the figures of the accompanying drawings in which like reference numerals refer to similar or identical elements. The elements of the drawings are not necessarily to scale relative to each other. The features of the various illustrated examples can be combined unless they exclude each other.

FIG. 1 shows a cross sectional view of a power module with a heat sink mounted on its external power connection.

FIG. 2 shows a power module with solid metal blocks mounted to the upper side of its external power connection.

FIG. 3 shows a power module with finned cooling bodies mounted to the upper side of its external power connection.

FIG. 4 shows a power module with a thermally conducting bar connecting the external power terminals on the lower side of the power module.

FIG. 5 shows a power module with a thermally conducting bar connecting the external power terminals on the upper bent parts of the external power terminals at the upper side of the power module.

FIG. 6 shows a perspective view of a power module and a cooler onto which the power module is mounted wherein a thermally conducting bar connecting the external power terminals on the lower side of the power module is also mounted onto the cooler.

FIG. 7 shows a power module with a connection bar connecting the external power terminals on the upper bent parts of the external power connections at the upper side of the power module wherein the external power terminals are connected to the connection bar on different sides of the connection bar.

FIG. 8 shows the external power terminals of FIG. 7 connected to the connection bar on different sides of the connection bar in a top view perspective.

FIG. 9 shows a power module and a cooler onto which the power module is mounted wherein a portion of the cooler comprises an elevated portion that is in contact with the external power connection.

FIG. 10 shows a power module and a cooler onto which the module is mounted wherein the external power connection is bent down to contact the cooler at the same plane as the power module.

### DETAILED DESCRIPTION

The power modules described herein may be a single sided coolable or double side coolable power module comprising one or more semiconductor dies mounted to a substrate and encapsulated by an encapsulant. To integrate the power module into a larger application a first external power connection is provided that is electrically connected to a first power terminal of at least one of one of the one or more semiconductor dies. A heatsink mounted to the first external power connection allows to homogenize and reduce peak temperatures occuring during operation of the power module, in particular at the external power connections and may thus allow higher performance operation of the power module. The terms external power connection, external power terminal, external terminal, external leads are used interchangeably in the following.

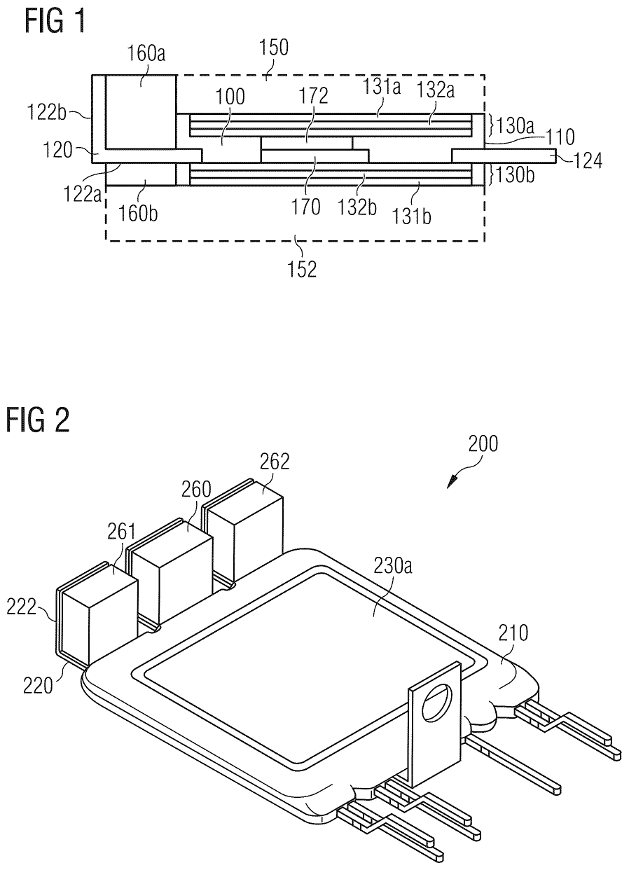

Referring to FIG. 1, a first exemplary power module 100 is depicted. The power module 100 comprises a semiconductor die 170 mounted onto a substrate 130b. The upper substrate 130a is optional and would provide a double side coolable power module. In a double side coolable power module the semiconductor die 170 may be thermally and/or electrically connected to the upper substrate 130a directly or via a spacer 172. For both variants, single side coolable and double side coolable, an external power connection 120 is mounted onto the substrate 130b or may be monolithically formed with the substrate 130b and provides an electrical connection of the semiconductor die 170 to the outside, e.g. a busbar, a PCB etc. An encapsulant 110 at least partially encapsulates the external power connection 120 wherein a portion of the external power connection 120 and at least parts of an outer surface 131b of the substrate 130b are exposed from the encapsulant 110. The insulating encapsulant 110 between the exposed electrically conducting material parts ensures the required creepage distances. A heatsink 160a, 160b is mounted to the external power connection 120, either below the external power connection as shown for heatsink 160b or above as shown for heatsink 160a or both.

In order to electrically isolate the power module 100 to the outside the substrates 130a and 130b may comprise an isolation layer 132a/b sandwiches between two electrical conducting layers, e.g. metal layers, such as but not limited to a direct copper bonding (DCB) substrate, an active metal brazed (AMB) substrate or an insulated metal substrate (IMS). The outer sides 131a and 131b of the substrates 130a, 130b may be mounted onto a cooler 150, 152 respectively. The inner electrically conducting layer may connect the semiconductor die 170 to the external power connection 120 of the power module 100. Depending on the shape of the heatsinks 160a, 160b and the shape of the coolers 150 and 152, the heatsinks 160a, 160b may optionally be mounted to a sidewall or a surface of the cooler. In order to guarantee electrical insulation, an insulating layer, such as but limited to a lamination foil or a thin ceramic layer (not shown in FIG. 1) has to be provided either between the heatsink 160a, 160b and the external power connection 120 or between the heatsink 160a, 160b and the cooler 150, 152. The power module 100 has a further external power connection 124 which may be positioned opposite the external power connection 120. Even though not shown, the external power connection 124 may also be equipped with a heatsink as shown for external power connection 120.

The power module 100 may comprise multiple semiconductor dies 170 arranged as a power conversion circuit, such as a DC to DC converter, DC to AC converter, etc. These power conversion circuits may comprise a half-bridge circuit which comprises a high-side switch connected in series with a low-side switch. The high-side and low-side switch may be provided by one or a group of discrete power transistor dies, MOSFETs, IGBTs, IGBTs and diodes, etc.

FIG. 2 shows an exemplary embodiment of a double side coolable power module 200 that comprises all features of power module 100 described herein above. The external power connection 120 of this exemplary embodiment comprises three external power terminals 120 each comprising a separate heatsink 260, 261, 262 mounted to an upper side of the respective external power terminal 120. The external power terminals 120 may be bent as shown in FIG. 2 such that they comprise a first part 122a and second part 122b that is bent by approximately 90°. The respective rectangular heatsinks 260, 261, 262 may be mounted on two sides to the L-shaped terminals. They can buffer heat generated temporarily during operation and thus reduce peak temperatures and avoid critical hot spots. The heatsink 260, 261, 262 may be solid metal blocks, made of but not limited to copper or aluminum.

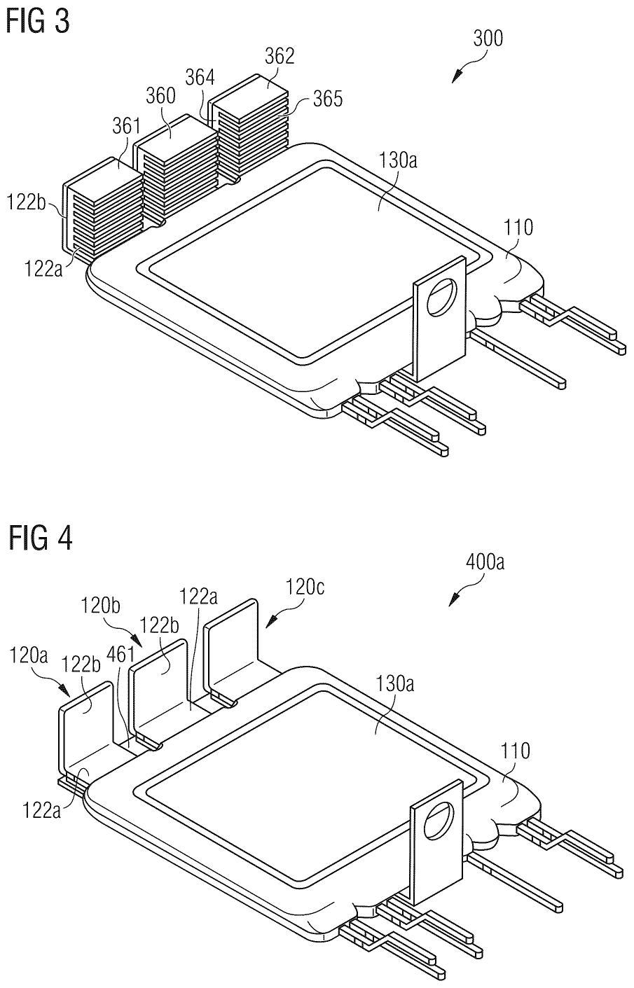

Alternatively, as shown in the power module 300 depicted in FIG. 3 that comprises all features of power module 100, the heatsinks 360, 361, 362 may also provide a fin structure 365 protruding from a continuous section 364.

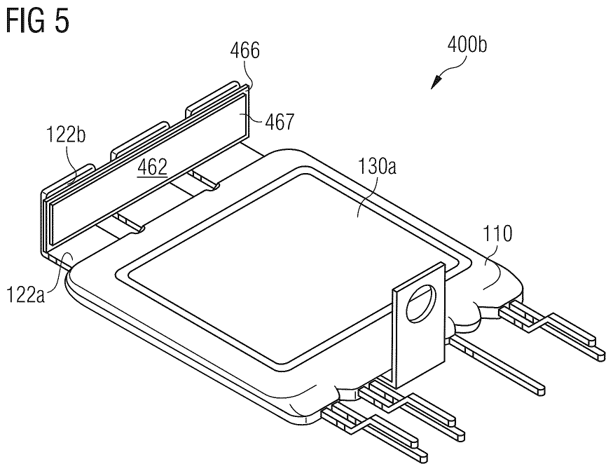

Referring to FIG. 4 a further exemplary power module 400a is depicted. Again, the power module 400a comprises all features of power module 100 and will only be described with regard to the differences to FIG. 1. The external power connection 120 of this embodiment comprises external power terminals 120a, 120b and 120c connected via a common heatsink 461. In case the external power terminals 120a, 120b and 120c convey direct currents of different polarity, the heatsink needs to be electrically isolated from at least one of the external power terminals 120a, 120b and 120c. During operation heat may be distributed between the external power terminals 120a, 120b and 120c to avoid hot spots. If for example the inner power terminal 120b conveys a direct current of a first polarity and the outer power terminals 120a and 120c convey a current of a second polarity, the inner power terminal 120b may become hotter than the two outer terminals, thus forming the bottle neck with regard to the current capability. The common heatsink 461 mounted to the lower side of the outer terminals 120 a-c may distribute the heat between the power terminals 120a-c more uniformly such that the overall current capability can be increased. In case two or more of the external power terminals 120a, 120b and 120c convey the same current phase, the heatsink 461 may also provide an electrical connection between those power terminals in addition to the thermal connection.

Alternatively or in addition, a common heatsink 462 may also be connected to the upper bent portion 122b of the external power terminals 120a-c as illustrated in power module 400b of FIG. 5. The power module 400b is similar to the power module 400a of FIG. 4 and will only be described with regard to the differences to FIG. 4. As shown exemplary the common heatsink 462 is formed of an insulating layer 466 connecting all three external power terminals. The insulating layer may comprise a ceramic, a laminate etc. In order to increase the thermal conductivity of the common heatsink 462, there may be further layer 467 connected to the other side of the common heatsink, such as but not limited to a metal layer which usually has a higher thermal conductivity than electrically insulating layers. Thus, the heat transfer from one external power terminal to another may further be increased compared to a pure insulating connection.

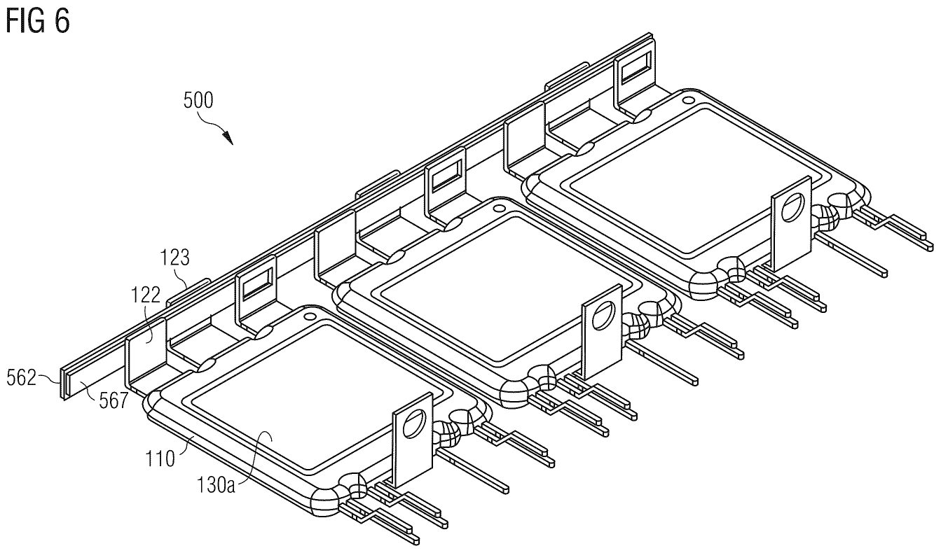

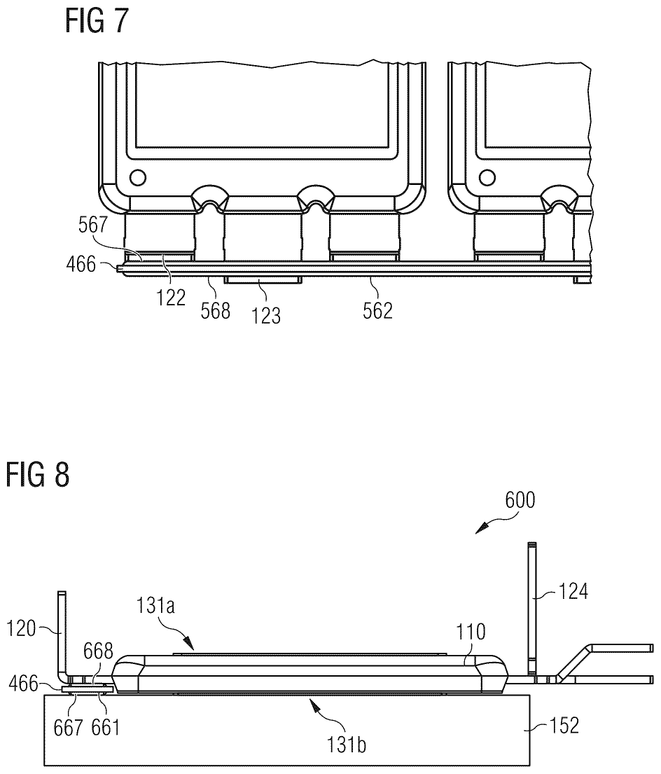

FIG. 6 shows a further embodiment of the present disclosure in which a power module assembly 500 comprises three power modules each similar to the power modules 400a and 400b shown in FIGS. 4 and 5. In contrast to the power modules 400a and 400b the external power connections may have different length. As shown the upward bent portion of the external power connection 522 may be connected to one side 567 of the common heatsink 562 wherein the external power connection 523 is longer or protrudes further out from the encapsulant 110 than the external power connection 522 and thus the bent portion of the external power connection 523 may be connected to the other side of the common heatsink 562. Again, as shown in FIG. 7, the common heatsink may consist only of an electrically insulating material 466 to distributed heat between the different power terminals, but may also have additional conducting layers 567, 568 mounted on respective sides of the insulating layer 466 and may be connected to one or more other power terminals to also provide electrical connection among subgroups of the external power connections. It is also possible to only use either layer 567 or 568. In the embodiment shown in FIG. 7 both layers 567 and 568 are used, each for a different polarity. When the heatsink 562 is used to connect external terminals of more than one semiconductor power module, the additional electrical connection between the external power terminals may further facilitate the connection to the outside circuitry (e.g. battery, capacitor, etc.) since the plurality of semiconductor power modules can be electrically connected in parallel. Slight electrical imbalances that may exist within one semiconductor power module may be effectively reduced due to the minimal distance between electrical connections of same potentials. Since opposing current flows (positive and negative) are kept in close proximity along the entire heatsink; magnetic fields generated by opposing currents cancel each other almost completely. Thus, the inductance may be reduced.

FIG. 8 shows a further embodiment of a power module assembly 600. The assembly is similar to the embodiment described in FIG. 4. The heatsink 661 comprises an insulating layer 466 sandwiched between two metal layers 667, 668, as in detail described with respect to FIGS. 6 and 7. The heatsink 661 is in direct contact with the cooler 152 onto which the heatsink 661 and the power module 600 are mounted. The lower side of the heatsink 661 and the lower side of the power module, e.g. the lower side of the exposed substrate 131b are coplanar in this example. In other words, the heatsink 661 bridges the gap between the power terminal 120 and the cooler 152.

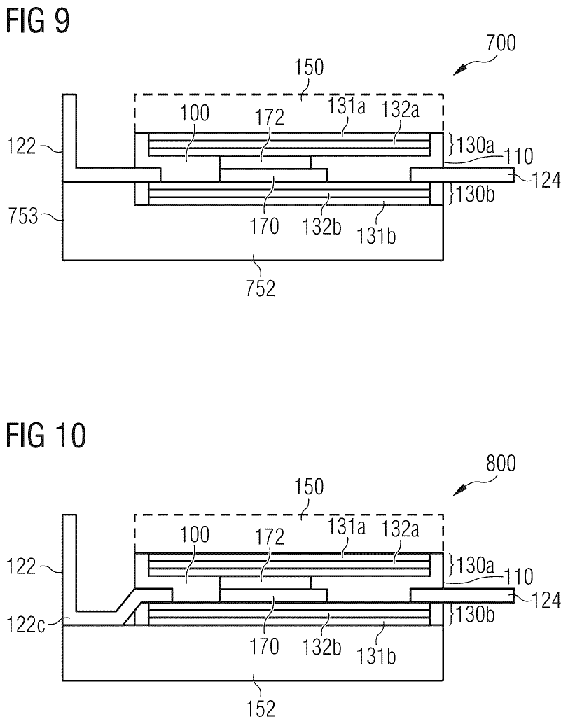

Alternatively, cooler and/or external power leads may be adapted in height/position as shown in FIGS. 9 and 10. FIG. 9 shows a similar arrangement of power module 100 and cooler as FIG. 1 and will only be described with regard to the differences to FIG. 1. The cooler 752 comprises a step portion 753 bridging the distance between the lower side of the power module 700, e.g. the lower side of the exposed outer surface 131b of the substrate 130b framed by the encapsulation 110, and the power terminal 120. In order to provide electrical isolation between the cooler 752 and the power terminal 120, an isolation needs to be provided between the two components, which may be but is not limited to a lamination foil, a thermal interface material, a ceramic, etc. which are not shown in FIG. 9.

Instead of elevating the cooler partially, the power terminal 120 may also be bent down 822c to be coplanar with the lower side of the power module 800 as shown in FIG. 10, in order to mount both power module 800 and the lower side of the power terminal 822c onto a planar cooler 152. As for the previous embodiment shown in FIG. 9 electrical isolation between the cooler and the power terminal needs to be provided between the two components, which may be implemented but is not limited to a lamination foil, a thermal interface material, a ceramic, etc.

Although the present disclosure is not so limited, the following numbered examples demonstrate one or more aspects of the disclosure.

Example 1: A power module comprising a substrate; one or more semiconductor dies mounted to the substrate; a first external power connection electrically connected to a first power terminal of at least one of the one or more semiconductor dies; an encapsulant at least partially encapsulating the first external power connection wherein a portion of the first external power connection and at least parts of an outer surface of the substrate are exposed from the encapsulant; a heatsink mounted to the first external power connection.

Example 2: The power module according to example 1, wherein the heatsink is configured to be thermally connected to a cooler mountable to the outer surface of the substrate.

Example 3: The power module according to example 2, wherein the heatsink is electrically isolated from the first external power connection by an isolation layer between the heatsink and the cooler or between the external power connection and the heatsink.

Example 4: The power module according to any of examples 1 to 3, wherein the heatsink is a massive metal block, preferably made of copper.

Example 5: The power module according to examples 1 or 2, wherein the heatsink comprises a continuous section along parts of the first external power connection and cooling structures protruding from the continuous section.

Example 6: The power module according to example 1, further comprising a second external power connection electrically connected to a second power terminal of at least one of the one or more semiconductor dies and separated from the first external power connection; the encapsulant at least partially encapsulating the second external power connection wherein an external end portion of the second external connection is exposed from the encapsulant; wherein the heatsink thermally connects parts of the exposed first and second external power connection.

Example 7: The power module according to example 6, wherein the first external power connection and the second external power connection are configured to carry currents of different polarity during operation.

Example 8: The power module according to example 6 or 7, wherein a surface of the heatsink that faces away from the first and second external power connections is coplanar with the outer surface of the substrate.

Example 9: The power module according to any of examples 6 to 8, wherein the outer surface of the substrate and the heatsink are configured to be mounted onto a cooler.

Example 10: The power module according to any of examples 6 to 9, wherein the heatsink comprises an isolation layer, preferably a ceramic.

Example 11: The power module according to example 10, wherein the isolation layer is sandwiched by two metal layers and the first external power connection is mounted to a first one of the two metal layers and the second external power connection is mounted to the second one of the two metal layers.

Example 12: A system comprising: a cooler, a power module according to example 1, wherein the substrate is mounted to a first surface of the cooler and wherein, the heatsink is an extension of the cooler extending beyond the encapsulation of the power module.

Example 13: The system according to example 12, wherein the cooler comprises a step portion and wherein the substrate is mounted onto the cooler in a first plane and the end portion of the first external power connection is mounted onto the cooler at a second plane different from the first plane.

Example 14: The system according to example 13, wherein the cooler has a flat surface and wherein parts of the external end portions of the first external power connection are formed to be coplanar with the outer surface of the substrate and mounted onto the extension of the cooler.

Example 15: A power module comprising a substrate; one or more semiconductor dies mounted to the substrate; a first external power connection electrically connected to a first power terminal of at least one of the one or more semiconductor dies; an encapsulant at least partially encapsulating the first external power connection wherein an external end portion of the first external power connection and at least parts of an outer surface of the substrate are exposed from the encapsulant; wherein parts of the external end portion of the first external power connection are bent to form a coplanar surface with the outer surface of the substrate that are exposed from the encapsulant.

Although specific examples have been illustrated and described herein, it will be appreciated by those of ordinary skill in the art that a variety of alternate and/or equivalent implementations may be substituted for the specific examples shown and described without departing from the scope of the present invention. This application is intended to cover any adaptations or variations of the specific examples discussed herein. Therefore, it is intended that this invention be limited only by the claims and the equivalents thereof.

It should be noted that the description and drawings merely illustrate the principles of the proposed methods and systems. Those skilled in the art will be able to implement various arrangements that, although not explicitly described or shown herein, embody the principles of the invention and are included within its spirit and scope. Furthermore, all examples and embodiments outlined in the present document are principally intended expressly to be only for explanatory purposes to help the reader in understanding the principles of the proposed methods and systems. Furthermore, all statements herein providing principles, aspects, and embodiments of the invention, as well as specific examples thereof, are intended to encompass equivalents thereof.

What is claimed is:

1. A power module, comprising:
a substrate;
one or more semiconductor dies mounted to the substrate;
a first external power connection electrically connected to a first power terminal of at least one of the one or more semiconductor dies;
an encapsulant at least partially encapsulating the first external power connection, wherein a portion of the first external power connection and at least parts of an outer surface of the substrate are exposed from the encapsulant; and
a heatsink mounted to the first external power connection.

2. The power module of claim 1, wherein the heatsink is configured to be thermally connected to a cooler mountable to the outer surface of the substrate.

3. The power module of claim 2, wherein the heatsink is electrically isolated from the first external power connection by an isolation layer, between the heatsink and the cooler or between the first external power connection and the heatsink.

4. The power module of claim 1, wherein the heatsink is a metal block.

5. The power module of claim 4, wherein the metal block is made of copper.

6. The power module of claim 1, wherein the heatsink comprises a continuous section along parts of the first external power connection and cooling structures protruding from the continuous section.

7. The power module of claim 1, further comprising a second external power connection electrically connected to a second power terminal of at least one of the one or more semiconductor dies and separated from the first external power connection, wherein the encapsulant at least partially encapsulates the second external power connection, wherein an external end portion of the second external power connection is exposed from the encapsulant, and wherein the heatsink thermally connects parts of the exposed first and second external power connections.

8. The power module of claim 7, wherein the first external power connection and the second external power connection are configured to carry currents of different polarity during operation.

9. The power module of claim 7, wherein a surface of the heatsink that faces away from the first and second external power connections is coplanar with the outer surface of the substrate.

10. The power module of claim 7, wherein the outer surface of the substrate and the heatsink are configured to be mounted onto a cooler.

11. The power module of claim 7, wherein the heatsink comprises an isolation layer.

12. The power module of claim 11, wherein the isolation layer is a ceramic.

13. The power module of claim 11, wherein the isolation layer is sandwiched by two metal layers, and wherein the first external power connection is mounted to a first one of the two metal layers and the second external power connection is mounted to the second one of the two metal layers.

14. A system, comprising:
a cooler; and
the power module of claim 1,
wherein the substrate is mounted to a first surface of the cooler, and
wherein the heatsink is an extension of the cooler extending beyond the encapsulation of the power module.

15. The system of claim 14, wherein the cooler comprises a step portion, wherein the substrate is mounted onto the cooler in a first plane, and wherein an end portion of the first external power connection is mounted onto the cooler at a second plane different from the first plane.

16. The system of claim 14, wherein the cooler has a flat surface, and wherein parts of the external end portions of the first external power connection are formed to be coplanar with the outer surface of the substrate and mounted onto the extension of the heatsink.

17. A power module, comprising:
a substrate;
one or more semiconductor dies mounted to the substrate;
a first external power connection electrically connected to a first power terminal of at least one of the one or more semiconductor dies; and
an encapsulant at least partially encapsulating the first external power connection,
wherein an external end portion of the first external power connection and at least parts of an outer surface of the substrate are exposed from the encapsulant,
wherein parts of the external end portion of the first external power connection are bent to form a coplanar surface with the outer surface of the substrate that is exposed from the encapsulant.
